(19) United States
(12) Patent Application Publication
(10) Pub. No.: US 2007/0187801 A1
(43) Pub. Date: Aug. 16, 2007

(54) Semiconductor device

(76) Inventors: Yoshiaki Asao, Sagamihara-shi (JP); Akihiro Nitayama, Yokohama-shi (JP)

Correspondence Address: OBLON, SPIVAK, MCCLELLAND, MAIER & NEUSTADT, P.C., 1940 DUKE STREET, ALEXANDRIA, VA, 22314, US

(21) Appl. No.: 11/397,726

(22) Filed: Apr. 5, 2006

(30) Foreign Application Priority Data
Feb. 10, 2006 (JP) 2006-033574

(51) Int. Cl. H01L 29/12; H01L 31/117

(52) U.S. Cl. 257/613; 257/616

(57) ABSTRACT

A semiconductor device comprising a semiconductor substrate, a switching element which is provided on the semiconductor substrate, a first interconnect layer which is provided above the semiconductor substrate, a plurality of phase-change memory devices which have phase-change material whose resistance changes by a phase-change due to a temperature change, being stacked, and being connected in series to the first interconnect layer and the switching element, a plurality of first heating elements which are connected in series to the respective phase-change memory devices, and a plurality of second heating elements which are connected to second interconnect layers different from the first interconnect layer, and which are provided so as to correspond to the respective phase-change memory devices.

### CROSS-REFERENCE TO RELATED APPLICATIONS

This application is based upon and claims the benefit of priority from prior Japanese Patent Application No. 2006-033574, filed Feb. 10, 2006, the entire contents of which are incorporated herein by reference.

### BACKGROUND OF THE INVENTION

1. Field of the Invention

The present invention relates to a semiconductor device having semiconductor memory devices, and in particular, to a phase-change random access memory in which semiconductor memory devices are configured by utilizing a substance whose resistance changes due to a phase-change associated with a temperature change.

2. Description of the Related Art

In recent years, a large number of semiconductor memory devices which store information on the basis of a novel principle of operation have been proposed. As one of them, a so-called phase-change random access memory (PRAM) is disclosed in, for example, Jpn. Pat. Appln. KOKAI Publication No. 2004-349709 or IEDM Tech. Dig. 2003, p. 901 “Novel Cell Structure of PRAM with Thin Metal Layer Inserted GeSbTe”. In the PRAM, semiconductor memory devices (memory cells) are configured by utilizing a chalcogenide substance, such as GeSbTe, whose resistance changes due to a change in a phase state (phase-change) associated with a temperature change. The chalcogenide substance changes in a phase state thereof between an amorphous state and a single-crystal state by a temperature change. The chalcogenide substance also has a difference in resistance thereof between the amorphous state and the single-crystal state. In the PRAM, a phase-change is brought about by Joule-heating onto the chalcogenide substance, and information of “1” or “0” is distinctly stored by utilizing the difference in resistance generated in accordance with the phase-change.

Specifically, in the PRAM disclosed in Jpn. Pat. Appln. KOKAI Publication No. 2004-349709, a memory cell is configured in such a manner that a chalcogenide substance layer (GeSbTe) 40 serving as a phase-change memory device, a heat generation unit 30 serving as a heating element, and a transistor 20 serving as a switching element are connected in series to a metal interconnect 50 serving as a bit line. The transistor 20 is made to be in an on-state due to a current flowing in a gate electrode serving as a word line, and is made to be in an off-state by shutting off the current to the gate electrode. Then, a read operation in a memory cell is carried out by selecting a bit line and a word line to read the resistance of the GeSbTe 40. Further, a write operation in a memory cell is carried out by selecting a bit line and a word line, and by changing a phase state of the GeSbTe 40 by use of Joule heat due to a current flowing in the transistor 20 from the bit line.

In order to increase memory capacity in a PRAM having such a structure, a configuration has been proposed in which, for example, the numbers of the chalcogenide substance layers 40 and the heat generation units 30 are pluralized, and they are connected in series to the metal interconnect 50. That is, a technology for increasing memory capacity of a PRAM by providing a plurality of pairs of the chalcogenide substance layers 40 and the heat generation units 30 so as to be stacked in a plurality of layers has been proposed.

However, in a structure in which the pairs of the chalcogenide substance layers 40 and the heat generation units 30 are merely stacked in a plurality of layers, the sum of the series resistances of the plurality of chalcogenide substance layers 40 is read in the read operation in the memory cell. More specifically, it is extremely difficult to respectively read separate resistances of the plurality of chalcogenide substance layers 40. Accordingly, it is extremely difficult to read which information is stored in which chalcogenide substance layer 40. In the same way, in a structure in which the pairs of the chalcogenide substance layers 40 and the heat generation units 30 are merely stacked in a plurality of layers, the plurality of chalcogenide substance layers 40 are collectively heated. More specifically, it is extremely difficult to selectively heat only a desired chalcogenide substance layer 40 and to change a resistance thereof among the plurality of chalcogenide substance layers 40. Accordingly, it is extremely difficult to selectively write desired information into a desired chalcogenide substance layer 40 among the respective chalcogenide substance layers 40.

In this way, in a structure in which a plurality of pairs of the chalcogenide substance layers 40 and the heat generation units 30 are merely stacked in a plurality of layers, it is extremely difficult to increase memory capacity of a PRAM in effect.

### BRIEF SUMMARY OF THE INVENTION

According to an aspect of the invention, there is provided a semiconductor device comprising: a semiconductor substrate; a switching element which is provided on the semiconductor substrate; a first interconnect layer which is provided above the semiconductor substrate; a plurality of phase-change memory devices which have phase-change material whose resistance changes by a phase-change due to a temperature change, and which are stacked so as to be connected in series to the first interconnect layer and the switching element; a plurality of first heating elements which are connected in series to the respective phase-change memory devices; and a plurality of second heating elements which are connected to second interconnect layers different from the first interconnect layer, and which are provided so as to correspond to the respective phase-change memory devices.

### BRIEF DESCRIPTION OF THE SEVERAL VIEWS OF THE DRAWING

FIG. 1 is a cross-sectional view schematically showing a configuration of a semiconductor device according to a first embodiment;

FIG. 2 is a view showing a principle of operation of memory devices provided in the semiconductor device shown in FIG. 1;

FIG. 3 is a cross-sectional view schematically showing a configuration of a semiconductor device according to a second embodiment;

FIG. 4 is a cross-sectional view schematically showing a configuration of a semiconductor device according to a third embodiment; and

FIG. 5 is a cross-sectional view schematically showing a configuration of a semiconductor device according to a fourth embodiment.

### DETAILED DESCRIPTION OF THE INVENTION

Hereinafter, respective embodiments according to the present invention will be described with reference to the drawings.

### FIRST EMBODIMENT

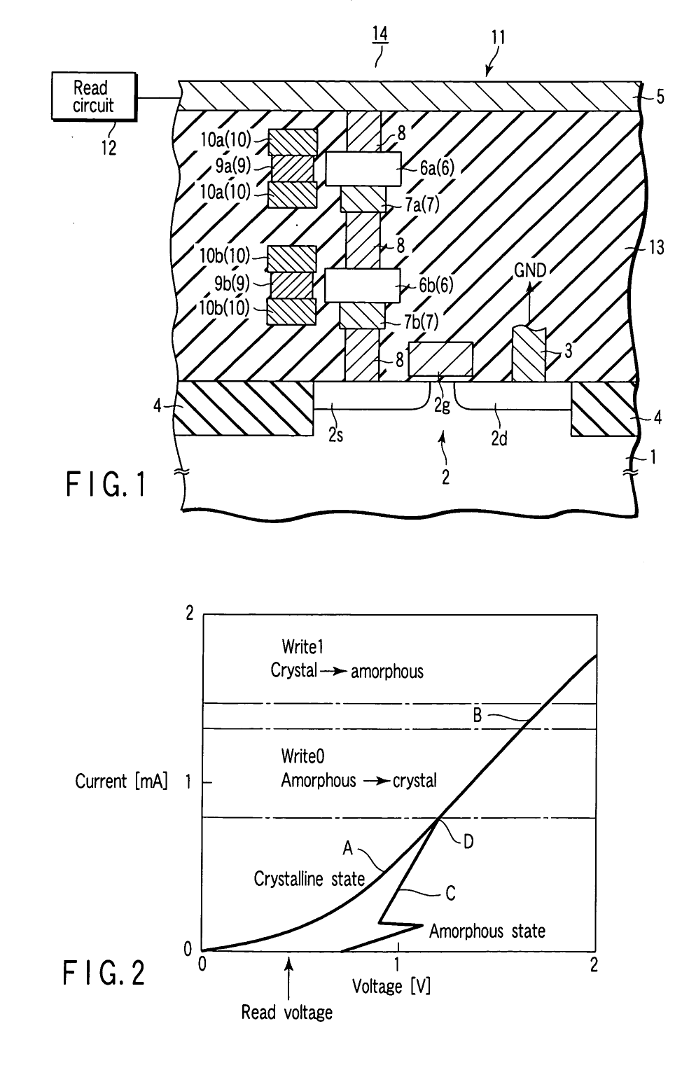

First, a first embodiment according to the present invention will be described with reference to FIGS. 1 and 2. FIG. 1 is a cross-sectional view schematically showing a configuration of a semiconductor device according to the embodiment. FIG. 2 is a view showing a principle of operation of memory devices provided in the semiconductor device shown in FIG. 1.

In the present embodiment, a plurality of phase-change memory devices are stacked in a plurality of layers so to form one-to-one pairs with a plurality of heating elements, and they are connected in series to a selective transistor serving as a switching element. Further, a plurality of write word lines are made to be adjacent to the respective phase-change memory devices so as to be insulated from the respective stacked phase-change memory devices, and are connected to other heating elements arranged in the vicinities of the respective phase-change memory devices. Thereby, a multilayer phase-change memory cell is configured to provide a high-capacity phase-change random access memory (PRAM). Hereinafter, this will be described in detail.

As shown in FIG. 1, a transistor (selective transistor) 2 serving as a switching element is provided on a surface layer portion of a semiconductor substrate 1. In the embodiment, a p-type silicon substrate is used as the semiconductor substrate 1. The transistor 2 is an N-channel MOSFET in which both of a source region 2s and a drain region 2d are formed from N⁺ type impurities. The source region 2s of the MOSFET 2 is connected in series to a first interconnect layer 5, phase-change memory devices 6, and first heating elements 7, etc. which will be described later. In addition, the drain region 2d of the MOSFET 2 is grounded via a ground interconnect (GND line) 3. Moreover, a gate electrode 2g of the MOSFET 2 serves as a read word line (RWL).

An operational state of the MOSFET2 is made to be in an on-state due to a current flowing in the read word line 2g. Further, an operational state of the MOSFET2 is made to be in an off-state by shutting off the current to the read word line 2g. Consequently, the MOSFET2 functions as a switching element which allows a current to flow into the phase-change memory devices 6, the first heating elements 7, and the like, or which shuts off the current made to flow into the phase-change memory devices 6, the first heating elements 7, and the like. The MOSFET 2 is insulated from other semiconductor devices (not shown) and the like which are provided on the surface layer portion of the p-type silicon substrate 1 by means of an isolation region (buried oxide film) 4 having a shallow trench isolation (STI) structure.

A bit line (BL) serving as a first interconnect layer 5 is provided above the p-type silicon substrate 1. Then, two phase-change memory devices 6 and two first heating elements 7 are respectively provided so as to be stacked in two layers between the bit line 5 and the p-type silicon substrate 1.

The respective phase-change memory devices 6 are made of phase-change materials whose resistance changes by bringing about a phase-change by a temperature change. In the present embodiment, as such a phase-change material, a chalcogenide-based material composed of a three-phase composite material including at least one of respective IV-B group elements, V-B group elements, and VI-B group elements is used. Specifically, the respective phase-change memory devices 6 are made of chalcogenide-based materials (GeSbTe: GST) composed of germanium (Ge) which is a IV-B group element, antimony (Sb) which is a V-B group element, and tellurium (Te) which is a VI-B group element. Further, in the present embodiment, the respective phase-change memory devices 6 are formed such that the sizes such as thicknesses and areas and the shapes thereof are made to be substantially the same.

The first heating elements 7 are respectively provided so as to be one-to-one pairs with the respective phase-change memory devices 6. More specifically, the first heating elements 7 are respectively connected in series to the respective phase-change memory devices 6 so as to directly contact the bottom faces thereof. The respective first heating elements 7 generate Joule heat due to a current flowing thereinto, and heat the respective phase-change memory devices 6 adjacent thereto. Consequently, temperatures of the respective phase-change memory devices 6 are changed, which brings about phase-changes thereof, and the resistances of the respective phase-change memory devices 6 are separately changed. The respective first heating elements (first heaters) 7 are made of, for example, tungsten (W) or the like.

Contact plugs (via plugs) 8 are provided respectively between the bit line 5 and the phase-change memory device 6a at the upper layer side, between the first heater 7a at the upper layer side and the phase-change memory device 6b at the lower layer side, and between the first heater 7b at the lower layer side and the source region 2s of the MOSFET 2. That is, all of the bit line 5, the phase-change memory device 6a and the first heater 7a at the upper layer side, the phase-change memory device 6b and the first heater 7b at the lower layer side, and the MOSFET 2 are connected in series via the contact plugs 8. The respective contact plugs 8 are made of, for example, tungsten (W) or the like.

In addition, second heating elements 9 are respectively provided one by one so as to be close one-to-one to the sides of the upper and lower phase-change memory devices 6a and 6b between the bit line 5 and the p-type silicon substrate 1. The upper and lower second heating elements (second heaters) 9a and 9b are made of, for example, tungsten (W) or the like in the same manner as in the upper and lower first heaters 7a and 7b described above. However, both of the upper and lower second heaters 9a and 9b are insulated from the upper and lower phase-change memory devices 6a and 6b, and the upper and lower first heaters 7a and 7b. In addition thereto, both of the upper and lower second heaters 9a and 9b are connected to second interconnect layers 10 which are electrically insulated from the bit line 5, the upper and lower phase-change memory devices 6a and 6b, and the MOSFET 2, etc.

More specifically, the second heater 9a at the upper layer side is provided so as to face the phase-change memory device 6a at the upper layer side while being sandwiched from the top and bottom by second interconnect layers 10a at the upper layer side. In the same way, the second heater 9b at the lower layer side is provided so as to face the phase-change memory device 6b at the lower layer side while being sandwiched from the top and bottom by the second interconnect layers 10b at the lower layer side. Both of the upper and lower second interconnect layers 10a and 10b function as write word lines (WWL). Further, it goes without saying that the upper and lower write word lines 10a and 10b are insulated from one another. The upper and lower second heaters 9a and 9b, in the same manner as in the upper and lower first heaters 7a and 7b described above, generate Joule heat due to a current flowing into the upper and lower second interconnect layers 10a and 10b, and thereby heat the upper and lower phase-change memory devices 6a and 6b which are close thereto.

Although not illustrated, the respective write word lines 10a and 10b provided so as to directly contact the top faces of the upper and lower second heaters 9a and 9b among the upper and lower write word lines 10a and 10b are formed so as to be extended toward the front side from the depth side in a paper space in FIG. 1. In addition, the respective write word lines 10a and 10b provided so as to directly contact the bottom faces of the upper and lower second heaters 9a and 9b among the upper and lower write word lines 10a and 10b are formed so as to be extended toward the depth side from the front side in a paper space in FIG. 1. That is, the respective write word lines 10a and 10b provided so as to directly contact the top faces of the upper and lower second heaters 9a and 9b, and the respective write word lines 10a and 10b provided so as to directly contact the bottom faces of the upper and lower second heaters 9a and 9b are formed to be extended in the opposite directions each other so as to sandwich the upper and lower second heaters 9a and 9b therebetween. Then, the directions in which the upper and lower write word lines 10a and 10b are extended are perpendicular to the direction from the upper and lower second heaters 9a and 9b toward the upper and lower phase-change memory devices 6a and 6b. According to such a configuration, the upper and lower write word lines 10a and 10b are in no danger of bringing about a short circuit failure or the like by contacting the upper and lower phase-change memory devices 6a and 6b and the upper and lower first heaters 7a and 7b.

As shown in FIG. 1, a double-layered structure multilayer phase-change memory cell 11 according to the present embodiment is configured by the MOSFET 2, the bit line 5, the upper and lower phase-change memory devices 6a and 6b, the upper and lower first heaters 7a and 7b, the upper and lower second heaters 9a and 9b, and the upper and lower write word lines 10a and 10b, etc. Further, a read circuit 12 which reads and store information stored in the upper and lower phase-change memory devices 6a and 6b is connected to the bit line 5.

Note that the upper and lower phase-change memory devices 6a and 6b, the upper and lower first heaters 7a and 7b, the upper and lower second heaters 9a and 9b, and the upper and lower write word lines 10a and 10b, etc, are provided in effect to one of a plurality of interlayer insulation films which are provided to be stacked in a plurality of layers on the silicon substrate 1. However, in the present embodiment, the plurality of interlayer insulation films which are provided so as to be stacked in a plurality of layers on the silicon substrate 1 are shown as a single-layered insulation film 13 in order to facilitate visualization of the drawings.

A principal part of a desired semiconductor device 14 according to the present embodiment is configured by the structure described above. That is, as shown in FIG. 1, the principal part of the phase-change random access memory (PRAM) 14, which has the multilayer phase-change memory cell 11 in which the two phase-change memory devices 6a and 6b are stacked in two layers so as to be serially connected, is configured.

Next, the operational principle of the upper and lower phase-change memory devices 6a and 6b will be described. Chalcogenide-based materials including GeSbTe have been known as a phase-change material whose resistance changes by bringing about a phase-change due to a temperature change. That is, a chalcogenide-based material functions as a conductive material having a low resistance in a crystalline (single-crystal) state, and functions as a resistive element having a high resistance in an amorphous state. It has been known that a chalcogenide-based material brings about a phase-change so as to trace different histories in accordance with a temperature at the time of heating or cooling the material, a time taken for heating or cooling the material.

For example, a chalcogenide-based material changes from the crystalline state to the amorphous state in accordance with a heat quantity added in a state in which a predetermined current is made to flow. Then, the chalcogenide-based material in the amorphous state further brings about a phase-change in accordance with a cooling process-thereof, and a resistance thereof changes. Specifically, when a chalcogenide-based material is cooled gradually and slowly in an amorphous state, the chalcogenide-based material brings about a phase-change in a crystalline state to become a conductive material, and a resistance thereof is lowered. However, when a chalcogenide-based material is cooled rapidly in an amorphous state, the chalcogenide-based material does not bring about a phase-change, and maintains the amorphous state as a resistive element and shows a high resistance. Such a change in a resistance with a phase-change is suitable for expressing “1” or “0” serving as a binary code. Therefore, a chalcogenide-based material is expected to be used as a material of a memory device.

Here, a mechanism of phase-change in a GeSbTe layer by which the upper and lower phase-change memory devices 6a and 6b are formed, and a write operation and a read operation of the upper and lower phase-change memory devices 6a and 6b will be concretely described. A current-voltage characteristic curve when a voltage is applied to a GeSbTe layer is shown in FIG. 2.

As shown in FIG. 2, the GeSbTe layer is in a crystalline state when a voltage applied thereto is low, and has a low resistance. This state is regarded as data “0”. In contrast thereto, the GeSbTe layer is in an amorphous state when a voltage applied thereto is high, and has a high resistance. This state is regarded as data “1”. In order to write data “1” into the GeSbTe layer having such a characteristic, operations which will be described below are carried out. Here, the GeSbTe layer is in a crystalline state as the initial state. First, a voltage to be applied to the GeSbTe layer is increased from zero until the value reaches from a crystalline state (data “0”) to a region in which Write 1 is inscribed. Then, the GeSbTe layer brings about a phase-change from the crystalline state to the amorphous state. That is, a phase-change in the region in which Write 1 is inscribed is brought about. Thereafter, a voltage to be applied to the GeSbTe layer is rapidly decreased. Then, the GeSbTe layer maintains the amorphous state without bringing about a phase-change. That is, the GeSbTe layer maintains the amorphous state functioning as a resistive material, and shows a high resistance. As a consequence, data “1” is written into the upper and lower phase-change memory devices 6a and 6b composed of the GeSbTe layer.

Such a phase-change means that the history which will be described hereinafter is traced on the hysteresis curve shown in FIG. 2. First, in the hysteresis curve shown in FIG. 2, a voltage applied to the GeSbTe layer is increased from zero along the curve shown by A. Subsequently, a voltage applied to the GeSbTe layer is increased along the curve shown by B. After a voltage applied to the GeSbTe layer reaches the region in which Write 1 is inscribed in FIG. 2, a voltage applied to the GeSbTe layer is lowered along the curve shown by B. Then, after a voltage applied to the GeSbTe layer reaches the diverging point D, a voltage applied to the GeSbTe layer is lowered along the curve shown by C. By tracing such a history, data “1” is written into the upper and lower phase-change memory devices (GeSbTe layers) 6a and 6b.

Moreover, in order to write data “0” into the GeSbTe layer, operations described hereinafter are carried out. Here, the GeSbTe layer is in an amorphous state as the initial state. That is, it is set such that a write operation of data “1” described above has been carried out in advance into the GeSbTe layer. Accordingly, a write operation described here is specifically an operation in which data recorded in the GeSbTe layer is rewritten from “1” to “0”. First, a voltage applied to the GeSbTe layer is increased until the voltage reaches a region in which Write 0 is inscribed from the amorphous state (data “1”). Then, the GeSbTe layer brings about a phase-change from the amorphous state to a crystalline state. That is, a phase-change in the region in which Write 0 is inscribed is brought about. Thereafter, a voltage applied to the GeSbTe layer is gradually and slowly decreased. Then, the GeSbTe layer maintains the crystalline state without bringing about a phase-change. That is, the GeSbTe layer maintains the crystalline state functioning as a conductive material, and shows a low resistance. As a consequence, data “0” is written into the upper and lower phase-change memory devices 6a and 6b composed of the GeSbTe layer.

Such a phase-change means that the history described hereinafter is traced on the hysteresis curve shown in FIG. 2. First, in the hysteresis curve shown in FIG. 2, a voltage applied to the GeSbTe layer is increased along the curve shown by C. Subsequently, a voltage applied to the GeSbTe layer is increased along the curve shown by B. After a voltage applied to the GeSbTe layer reaches the region in which Write 0 is inscribed in FIG. 2, a voltage applied to the GeSbTe layer is lowered along the curve shown by B. Then, after a voltage applied to the GeSbTe layer reaches the diverging point D, a voltage applied to the GeSbTe layer is lowered along the curve shown by A. By tracing such a history, data in the upper and lower phase-change memory devices (GeSbTe layers) 6a and 6b are rewritten from “1” to “0”.

The principle of a write operation of the upper and lower phase-change memory devices 6a and 6b by utilizing a difference in a resistance with a phase-change in the GeSbTe layer has been described above. In order to read a data “0” or “1” written into the upper and lower phase-change memory devices 6a and 6b, it suffices to read the resistances of the upper and lower phase-change memory devices 6a and 6b. This is the principle of a read operation of the upper and lower phase-change memory devices 6a and 6b.

Next, an operational principle of the multilayer phase-change memory cell 11 provided in the PRAM 14 according to the present embodiment will be described. First, a data write operation into the upper and lower phase-change memory devices (memory cells) 6a and 6b provided in the multilayer phase-change memory cell 11 will be described.

First, by applying a predetermined voltage to the gate electrode (read word line) 2g of the MOSFET 2, the switching function of the MOSFET 2 is made to be in an on-state. Then, a current flows between the source region 2s and the drain region 2d of the MOSFET 2, and a current also flows into the upper and lower phase-change memory devices 6a and 6b and the upper and lower first heaters 7a and 7b. Thereby, the upper and lower first heaters 7a and 7b respectively heat the upper and lower phase-change memory devices 6a and 6b. The upper and lower phase-change memory devices 6a and 6b bring about a phase-change described above in accordance with a heating value thereof, or a heat quantity transmitted from the upper and lower first heaters 7a and 7b.

Thereafter, the switching function of the MOSFET 2 is made to be in an off-state by stopping an application of voltage to the read word line 2g of the MOSFET 2. Then, a current does not flow between the source region 2s and the drain region 2d of the MOSFET 2, and a current also does not flow into the upper and lower phase-change memory devices 6a and 6b and the upper and lower first heaters 7a and 7b. Thereby, the upper and lower first heaters 7a and 7b respectively stop to heat the upper and lower phase-change memory devices 6a and 6b, and cool the upper and lower phase-change memory devices 6a and 6b. As a result, the upper and lower phase-change memory devices 6a and 6b are made to be in the single-crystal state or amorphous state as described above. In other words, binary data of “0” or “1” is written into the upper and lower phase-change memory devices 6a and 6b.

In the present embodiment, when such a data write operation into the upper and lower phase-change memory devices 6a and 6b is carried out, the read word line (RWL) 2g and the bit line (BL) 5 are selected, and one of the two write word lines (WWL) 10a and 10b is selected. That is, phase-changes are brought about in the upper and lower phase-change memory devices 6a and 6b by utilizing, not only the effect of heat generation of the upper and lower phase-change memory devices 6a and 6b themselves and the effect of heating by the upper and lower first heaters 7a and 7b, but also the effect of heating by the upper and lower second heaters 9a and 9b arranged so as to be close one-to-one to the upper and lower phase-change memory devices 6a and 6b. More specifically, a phase-change is brought about in one of the upper and lower phase-change memory devices 6a and 6b. The phase-change is brought about by a summation of Joule heat generated by the upper and lower phase-change memory devices 6a and 6b and the upper and lower first heaters 7a and 7b due to a write current flowing between the read word line (RWL) 2g and the bit line (BL) 5, and Joule heat generated by one of the upper and lower second heaters 9a and 9b due to a current flowing in one of the respective write word lines (WWL) 10a and 10b.

As a consequence, a phase-change is brought about selectively in only one of the upper and lower phase-change memory devices 6a and 6b, so that binary data of “0” or “1” can be written into only one of the upper and lower phase-change memory devices 6a and 6b. That is, in the multilayer phase-change memory cell 11 of the present embodiment, selectivity is provided to a data write operation into the upper and lower phase-change memory devices 6a and 6b which are stacked and serially connected, whereby data can be independently written respectively into the upper and lower phase-change memory devices 6a and 6b.

Next, a data read operation from the upper and lower phase-change memory devices 6a and 6b will be described. In the multilayer phase-change memory cell 11 of the embodiment, data written in the upper and lower phase-change memory devices 6a and 6b are read by reading a combined resistance (series resistance) of the upper and lower phase-change memory devices 6a and 6b which are stacked and connected in series. For this reason, a sequence described hereinafter is required.

First, one of the upper and lower phase-change memory devices 6a and 6b is selected, and information on a current flowing therein is read. Then, the information on a current is stored as data A in a capacitor (not shown) provided in the read circuit 12 connected to the bit line (BL) 5. Next, data “1” is written in a memory cell 11 which includes the one of the selected upper and lower phase-change memory devices 6a and 6b, as an expected value. Thereafter information on a current flowing the memory cell 11 is read as data B. The read information B on a current is compared with the information A on a current stored in advance. When it is A=B, the data recorded in the selected one of the phase-change memory devices 6a and 6b is regarded as “1”. When it is A≠B, the data recorded in the selected one of the phase-change memory devices 6a and 6b is regarded as “0”. Accordingly, the data written in the upper and lower phase-change memory devices 6a and 6b can be respectively read independently and selectively from the upper and lower phase-change memory devices 6a and 6b.

For example, the upper and lower phase-change memory devices 6a and 6b provided in the multilayer phase-change memory cell 11 are formed so as to have sizes and shapes which are substantially the same as each other as described above. For this reason, the resistances, in the crystalline state and in the amorphous state, of the upper and lower phase-change memory devices 6a and 6b show values which are substantially the same as each other. Here, suppose that a resistance of the upper and lower phase-change memory devices 6a and 6b in the crystalline state is 100Ω. Further, suppose that a resistance of the upper and lower phase-change memory devices 6a and 6b in the amorphous state is 1000Ω. In this case, a combined resistance (series resistance) of the upper and lower phase-change memory devices 6a and 6b is one of 200Ω, 1100Ω, and 2000Ω. However, a combined resistance of the upper and lower phase-change memory devices 6a and 6b is 1100Ω in, for examples, two cases; that is, a case in which a resistance of the upper phase-change memory device 6a is 100Ω, and a resistance of the lower phase-change memory device 6b is 1000Ω, and a case in which a resistance of the upper phase-change memory device 6a is 1000Ω, and a resistance of the lower phase-change memory device 6b is 100Ω.

In such a case, as described in the background of the invention, it is approximately impossible to distinguish between the cases in two ways in a semiconductor memory device disclosed in, for example, Jpn. Pat. Appln. KOKAI Publication No. 2004-349709, the semiconductor memory device having the structure in which a plurality of pairs of chalcogenide substance layers 40 and the heat generation units 30 are merely stacked in a plurality of layers so as to be connected in series to one another. In other words, it is extremely difficult to increase memory capacity of a PRAM in effect.

In contrast thereto, in the multilayer phase-change memory cell 11 provided in the PRAM 14 according to the present embodiment, as described above, both of a data write operation into the upper and lower phase-change memory devices 6a and 6b which are stacked so as to be connected in series, and a data read operation from the upper and lower phase-change memory devices 6a and 6b can be independently and selectively carried out for each of the upper and lower phase-change memory devices 6a and 6b. That is, it is possible to distinguish the cases in two ways described above. Accordingly, in the PRAM 14 according to the embodiment, the phase-change memory devices 6a and 6b are stacked so as to be connected in series, whereby the memory capacities can be increased.

As described above, according to the first embodiment, the multilayer phase-change random access memory 14 can be provided in which an attempt is made to increase the memory capacity by provided a plurality of phase-change memory devices 6 so as to be stacked in a plurality of layers.

### SECOND EMBODIMENT

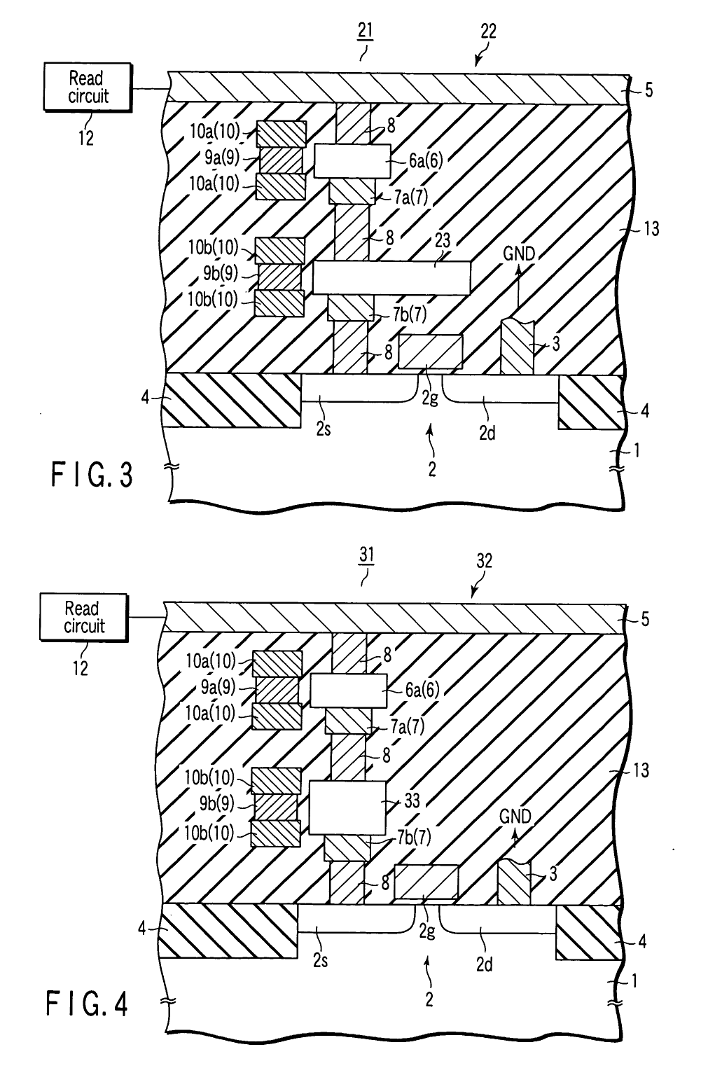

Next, a second embodiment according to the present invention will be described with reference to FIG. 3. FIG. 3 is a cross-sectional view schematically showing a configuration of a semiconductor device according to the present embodiment. Note that the same functional components as those of the first embodiment are denoted by the same reference numbers, and detailed description thereof is omitted.

In the present embodiment, differently from the first embodiment, two phase-change memory devices (memory cells) having different resistances are stacked so as to be connected in series. Hereinafter, it will be described concretely.

As shown in FIG. 3, in a multilayer phase-change memory cell 22 provided in a PRAM 21 according to the present embodiment, the phase-change memory device 6a and a phase-change memory device 23 whose sizes and areas are different from each other are stacked in two layers so as to be connected in series above and below. Specifically, the phase-change memory device 23 at the lower layer side is formed so as to be larger and to have broader areas of both of the upper and lower principal surfaces thereof than the phase-change memory device 6a at the upper layer side. As a consequence, a resistance of the phase-change memory device 23 at the lower layer side is made lower than that of the phase-change memory device 6a at the upper layer side in the both states of a crystalline state and an amorphous state.

As described above, according to the second embodiment, the same effect as that in the first embodiment can be obtained. Because the resistances of the upper and lower phase-change memory devices 6a and 23 are different from each other, there is no danger of bringing about a case in which the combined resistances of the upper and lower phase-change memory devices 6a and 23 are redundant as described in the first embodiment. For example, suppose that a resistance of the phase-change memory device 6a at the upper layer side in a crystalline state is 100Ω. Further, suppose that a resistance of the phase-change memory device 6a at the upper layer side in an amorphous state is 1000Ω. In contrast thereto, suppose that a resistance of the phase-change memory device 23 at the lower layer side in a crystalline state is 50Ω. Further, suppose that a resistance of the phase-change memory device 23 at the lower layer side in an amorphous state is 500Ω. In this case, a combined resistance (series resistance) of the upper and lower phase-change memory devices 6a and 23 is one of 150Ω, 600Ω, 1050Ω, and 1500Ω.

Accordingly, in the PRAM 21 of the embodiment, it suffices to carry out one-time data read operation from the upper and lower phase-change memory devices 6a and 23, differently from the PRAM 14 in the first embodiment. As a result, according to the present embodiment, the multilayer phase-change random access memory 21 in which a speed of read operation is improved can be provided.

### THIRD EMBODIMENT

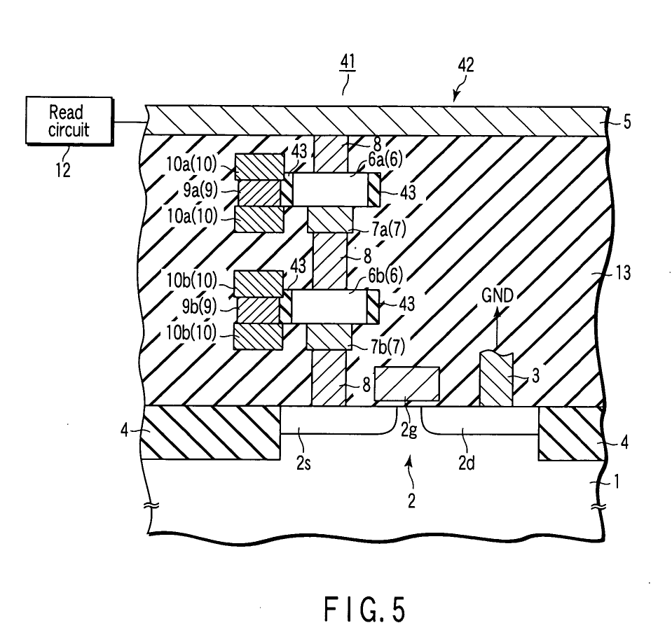

Next, a third embodiment according to the present invention will be described with reference to FIG. 4. FIG. 4 is a cross-sectional view schematically showing a configuration of a semiconductor device according to the present embodiment. Note that the same functional components as those of the first and second embodiments are denoted by the same reference numbers, and detailed description thereof is omitted.

In the present embodiment as well, two phase-change memory devices (memory cells) having different resistances are stacked so as to be connected in series, in the same manner as in the second embodiment. Hereinafter, it will be described concretely.

As shown in FIG. 4, in a multilayer phase-change memory cell 32 provided in a PRAM 31 according to the present embodiment, the phase-change memory device 6a and a phase-change memory device 23 whose thicknesses are different from each other are stacked in two layers above and below so as to be connected in series. Specifically, the phase-change memory device 33 at the lower layer side is formed so as to be thicker than the phase-change memory device 6a at the upper layer side. Consequently, a resistance of the phase-change memory device 33 at the lower layer side is made higher than that of the phase-change memory device 6a at the upper layer side in both states of a crystalline state and an amorphous state.

As described above, according to the third embodiment, the same effect as that in the first and second embodiments can be obtained. Further, in the same manner as in the second embodiment, there is no danger of bringing about a case in which a combined resistance of the upper and lower phase-change memory devices 6a and 33 are redundant. For example, suppose that a resistance of the phase-change memory device 6a at the upper layer side in a crystalline state is 100Ω. Further, suppose that a resistance of the phase-change memory device 6a at the upper layer side in an amorphous state is 1000Ω. In contrast thereto, suppose that a resistance of the phase-change memory device 33 at the lower layer side in a crystalline state is 200Ω. Further, suppose that a resistance of the phase-change memory device 33 at the lower layer side in an amorphous state is 2000Ω. In this case, a combined resistance (series resistance) of the upper and lower phase-change memory devices 6a and 33 is one of 300Ω, 1200Ω, 2100Ω, and 3000Ω.

Accordingly, in the PRAM 31 of the embodiment, it suffices to carry out one-time data read operation from the upper and lower phase-change memory devices 6a and 33, differently from the PRAM 14 in the first embodiment. As a result, according to the present embodiment, the multilayer phase-change random access memory 31 in which a speed of read operation is improved can be provided in the same manner as in the PRAM 21 of the second embodiment.

### FOURTH EMBODIMENT

Next, a fourth embodiment according to the present invention will be described with reference to FIG. 5. FIG. 5 is a cross-sectional view schematically showing a configuration of a semiconductor device according to the present embodiment. Note that the same functional components as those of the first to third embodiments are denoted by the same reference numbers, and detailed description thereof is omitted.

In the present embodiment, the upper and lower phase-change memory devices 6a and 6b, and the upper and lower second heaters 9a and 9b are formed so as to be spaced from each other in a self-aligning manner. Hereinafter, it will be described concretely.

As shown in FIG. 5, in a multilayer phase-change memory cell 42 provided in a PRAM 41 according to the present embodiment, sidewall films 43 made of an insulating material are formed at both sides of the sides of the upper and lower phase-change memory devices 6a and 6b. The respective sidewall films 43 are composed of, for example, an SiN film. Accordingly, the upper and lower phase-change memory devices 6a and 6b, the upper and lower second heaters 9a and 9b, and the upper and lower write word lines 10a and 10b are formed so as to sandwich the sidewall films 43 thereamong.

As described above, according to the fourth embodiment, the same effect as those of the first to third embodiments can be obtained. Further, in the present embodiment, the upper and lower phase-change memory devices 6a and 6b, the upper and lower second heaters 9a and 9b, and the upper and lower write word lines 10a and 10b are formed so as to sandwich the sidewall films 43 thereamong. As a consequence, the upper and lower phase-change memory devices 6a and 6b, the upper and lower second heaters 9a and 9b, and the upper and lower write word lines 10a and 10 b are made to be spaced from each other in a self-aligning manner. According to such a forming method, while the upper and lower phase-change memory devices 6a and 6b, the upper and lower second heaters 9a and 9b, and the upper and lower write word lines 10a and 10b are insulated from one another, those spaces can be narrowed. That is, it is possible that, while avoiding the risk that the upper and lower phase-change memory devices 6a and 6b, the upper and lower second heaters 9a and 9b, and the upper and lower write word lines 10a and 10b bring about short-circuit failure, a cell area of the multilayer phase-change memory cell 42 is reduced. As a result, according to the present embodiment, a compact multilayer phase-change random access memory 41 which is downsized can be provided.

Note that the semiconductor device according to the present invention is not limited to the first to fourth embodiments. The semiconductor device according to the invention can be executed by changing those structures thereof, or some of the manufacturing processes in various settings, or by appropriately combining various settings to use within a range which does not deviate from the gist of the present invention.

For example, materials used for the phase-change memory devices 6a, 6b, 23, and 33 are not necessarily limited to chalcogenide-based materials including GeSbTe described above. Materials used for the phase-change memory devices 6a, 6b, 23, and 33 may be phase-change materials whose resistance changes by bringing about a phase-change due to a temperature change.

Further, all compositional ratios of the materials forming the phase-change memory devices 6a, 6b, 23, and 33 are not necessarily a same value. It suffices for the compositional ratios of the materials forming the phase-change memory devices 6a, 6b, 23, and 33 to be appropriately set to proper values in consideration of a compositional ratio of a memory device to be combined with, a current made to flow, a voltage to be applied, a resistance to be determined, a position of stacking, or a material of a peripheral component. Accordingly, it suffices for the respective resistances in a crystalline state and in an amorphous state of the phase-change memory devices 6a, 6b, 23, and 33 to be appropriately set to proper values in consideration of a resistance of a memory device to be combined with, a current made to flow, a voltage to be applied, a resistance to be determined, or the like.

Furthermore, the number of stacking of the phase-change memory devices 6a, 6b, 23, and 33 is not necessarily limited to being in two layers described above. The phase-change memory devices 6a, 6b, 23, and 33 may be stacked in three or more layers. The phase-change memory devices 6a, 6b, 23, and 33 are stacked in three or more layers, whereby the memory capacities of the PRAMs 14, 21, 31, and 41 can be further improved.

In addition, combinations of the phase-change memory devices 6a, 6b, 23, and 33 to be stacked are not necessarily limited to the combinations in the first to fourth embodiments described above. It goes without saying that, for example, the phase-change memory device 23 used in the second embodiment and the phase-change memory device 33 used in the third embodiment may be combined to be stacked.

Moreover, the upper and lower first heaters 7a and 7b which are connected in series to the phase-change memory devices 6a, 6b, 23, and 33 are not necessarily provided so as to directly contact the bottom faces of the phase-change memory devices 6a, 6b, 23, and 33. The upper and lower first heaters 7a and 7b may be provided so as to directly contact the top faces of the phase-change memory devices 6a, 6b, 23, and 33. Alternatively, the upper and lower first heaters 7a and 7b may be provided to be close to the phase-change memory devices 6a, 6b, 23, and 33 so as to be spaced from each other, without directly contacting the top faces and the bottom faces thereof. It suffices for the upper and lower first heaters 7a and 7b to be arranged at positions where the phase-change memory devices 6a, 6b, 23, and 33 with which those face one-to-one can be independently and selectively heated.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor device comprising:
a semiconductor substrate;
a switching element which is provided on the semiconductor substrate;
a first interconnect layer which is provided above the semiconductor substrate;
a plurality of phase-change memory devices which have phase-change material whose resistance changes by a phase-change due to a temperature change, being stacked, and being connected in series to the first interconnect layer and the switching element;
a plurality of first heating elements which are connected in series to the respective phase-change memory devices; and
a plurality of second heating elements which are connected to second interconnect layers different from the first interconnect layer, and which are provided so as to correspond to the respective phase-change memory devices.

2. The device according to claim 1, wherein
the phase-change material is a chalcogenide-based material composed of a three-phase composite material including at least one of respective IV-B group elements, V-B group elements, and VI-B group elements.

3. The device according to claim 1, wherein
the phase-change memory devices whose areas are different from one another are included.

4. The device according to claim 1, wherein
the phase-change memory devices whose thicknesses are different from one another are included.

5. The device according to claim 1, wherein
the respective phase-change memory devices and the respective second heating elements are formed so as to be spaced from each other in a self-aligning manner.

6. The device according to claim 1, wherein
a data is independently and selectively written into the phase-change memory device by heating the first heating element and the second heating element with flowing a current through between the first interconnect layer and the switching element, and flowing a current through the second interconnect layer.

7. The device according to claim 1, wherein
a data written in the phase-change memory device is independently and selectively determined by comparing an information on a current flowing through the phase-change memory device with an information on a current flowing through the memory cell written an expected value.

8. The device according to claim 1, wherein
the respective phase-change memory devices are changed in temperature by a summation of Joule heat generated by the respective phase-change memory devices themselves, and Joule heat generated by the respective first heating elements and the respective second heating elements.

9. The device according to claim 1, wherein
the respective first heating elements are connected in series so as to directly contact the respective phase-change memory devices respectively, or so as to be close to the respective phase-change memory devices, and the first heating elements respectively heat the respective phase-change memory devices independently and selectively.

10. The device according to claim 1, wherein
the respective first heating elements are connected in series so as to directly contact at least one side of top faces and bottom faces of the respective phase-change memory devices.

11. The device according to claim 1, wherein
the respective second heating elements are provided one by one to the respective phase-change memory devices so as to face one-to-one, and respectively heat the respective phase-change memory devices independently and selectively.

12. The device according to claim 1, wherein
the respective second heating elements are insulated from the respective phase-change memory devices and the respective first heating elements.

13. The device according to claim 1, wherein
the respective second heating elements are spaced with the respective phase-change memory devices in a self-aligning manner so as to sandwich sidewall films composed of insulators provided at sides of the respective phase-change memory devices.

14. The device according to claim 1, wherein
the phase-change memory devices whose resistances are different from one another are included.

15. The device according to claim 1, wherein
the phase-change material is GeSbTe.

16. The device according to claim 1, wherein
the switching element is a MOSFET.

17. The device according to claim 1, wherein
one electrode among a plurality of electrodes which the switching element has serves as a read word line.

18. The device according to claim 1, wherein
the first interconnect layer is a bit line.

19. The device according to claim 1, wherein
the respective second interconnect layers are write word lines.

20. The device according to claim 1, further comprising:
a read circuit which reads and stores information stored in the respective phase-change memory devices, the read circuit being connected to the first interconnect layer.
